(19) United States
(12) Patent Application Publication
(10) Pub. No.: US 2017/0104470 A1
(43) Pub. Date: Apr. 13, 2017

(54) INTERDIGITATED TRANSDUCERS AND REFLECTORS FOR SURFACE ACOUSTIC WAVE DEVICES WITH NON-UNIFORMLY SPACED ELEMENTS

(71) Applicant: Avago Technologies General IP (Singapore) Pte. Ltd., Singapore (SG)

(72) Inventors: Bernhard Koelle, Milpitas, CA (US); Anatoly Rusakov, San Jose, CA (US)

(21) Appl. No.: 14/879,684

(22) Filed: Oct. 9, 2015

(51) Int. Cl. H03H 9/02; H03H 9/25

(52) U.S. Cl. CPC H03H 9/02708; H03H 9/25; H03H 9/02535

(57) ABSTRACT

A surface acoustic wave (SAW) device includes: a substrate, an interdigitated transducer including a plurality of interdigitated fingers disposed on a first surface of the substrate, and a reflector including a plurality of gratings also disposed on the first surface. At least one of: (1) a first group of the interdigitated fingers has a first finger pitch and a first finger metal pitch ratio, and a second group of the interdigitated fingers has a second finger pitch different from the first metal pitch and a second metal pitch ratio different from the first metal pitch ratio; and (2) a first group of the gratings has a first grating pitch and a first grating metal pitch ratio, and a second group of the gratings has a second grating metal pitch different from the first grating metal pitch and a second grating metal pitch ratio different from the first grating metal pitch ratio.

### BACKGROUND

There is an increasing demand for communication devices capable of operating across a variety of different frequency bands. For example, there is an increasing demand for cellular or mobile telephones that can operate in multiple frequency bands. In such devices, separate transmit and receive filters are in general employed for each transmit and receive frequency band. In practice, various types of resonators may be used to produce such filters. For example, ladder or lattice type filters may include an acoustic resonator, in particular a surface acoustic wave (SAW) resonator.

FIG. 1A illustrates an exemplary acoustic resonator. In particular, FIG. 1A shows a view of a one-port SAW device 10. SAW device 10 includes an upper metal layer 12 disposed on a substrate 14, which is typically made of a piezoelectric material such as LiTaO3 (Lithium Tantalate) or LiNbO3 (Lithium Niobate). Metal layer 12 is patterned to form an interdigitated transducer 16 and two reflectors (e.g., reflector gratings) 18. Interdigitated transducer 16 includes a plurality of fingers 19 and reflectors 18 include a plurality of gratings 17.

In operation, a signal, typically at an RF frequency, is coupled between a first terminal 11 and a second terminal 13 and SAW device 10 presents a resonance impedance characteristic to the signal at a resonant frequency which is determined by various physical parameters of SAW device 10, including the spacing between interdigitated fingers 19 and the velocity of sound in the substrate 14.

FIG. 1B illustrates another exemplary acoustic resonator. In particular, FIG. 1B shows a view of a two-port SAW device 15, more particularly a SAW filter. SAW device 15 includes first and second interdigitated transducers 16-1 and 16-2, and two reflectors 18. First and second interdigitated transducers 16-1 and 16-2 are separated and spaced apart from each other by a delay line.

In operation, an input signal, typically at an RF frequency, is provided between the input terminal IN and ground of first interdigitated transducer 16-1. The input signal launches an acoustic wave at the surface of substrate 14 which is received at second interdigitated transducer 16-2 and which is output, again typically at an RF frequency, between the output terminal OUT and ground. Typically, SAW device 15 applies a passband filtering function to the input signal to yield the output signal, where the filter function is determined by several physical parameters of SAW device 15, including the spacing between the fingers 19 and the velocity of sound in the substrate 14.

FIG. 2 shows a cross-sectional view of another acoustic resonator. In particular, FIG. 2 shows a view of a one-port SAW device 20. SAW device 20 is similar to SAW device 10 in construction and operation, with SAW device 20 having a hybrid wafer substrate 240. In particular, substrate 240 comprises a relatively thin top layer 242 of a piezoelectric material such as Lithium Tantalate or Lithium Niobate on (e.g., bonded to) a thicker base layer 244. In some embodiments, the top piezoelectric material layer 242 may have a thickness which is on the order of a few (e.g., six to ten) wavelengths of the acoustic signal propagating in SAW filter 20. Typically, base layer 244 is made of a different material than material layer 242, with a different or compensating temperature coefficient of frequency (TCF), such as silicon, sapphire, glass etc. The use of a hybrid substrate 240 as described above may improve the temperature coefficient of frequency (TCF) of surface SAW device 20, over the range of operating temperatures and conditions.

However, it has been observed that the use of a hybrid substrate can lead to large spurious resonance responses in the filter characteristics. In particular, these spurious resonance responses are generated at frequencies higher than the anti-resonant frequency of SAW device 20. These spurious resonance responses can end up in the passband of another device in an overall system which includes SAW device 20. This will then degrade the in-band performance of that other passband.

It would be desirable, therefore, to provide an acoustic resonator with a structural configuration which can provide some mitigation of spurious resonance responses, particularly spurious resonance responses generated when a hybrid wafer substrate is employed.

### SUMMARY

In one aspect of the invention, a surface acoustic wave (SAW) device may include a substrate and at least a first interdigitated transducer disposed on a first surface of the substrate. The first interdigitated transducer may include a plurality of interdigitated fingers, including at least a first group of first interdigitated fingers having a first finger pitch and a second group of second interdigitated fingers having a second finger pitch which is different from the first finger pitch. The first group of first interdigitated fingers may have a first finger metal pitch ratio, and the second group of second interdigitated fingers has a second finger metal pitch ratio which is different from the first finger metal pitch ratio. The first group of first interdigitated fingers may have a first surface mode resonance frequency, and the second group of second interdigitated fingers has a second surface mode resonance frequency which is substantially the same as the first surface mode resonance frequency.

In another aspect of the invention, a surface acoustic wave (SAW) device may include: a substrate; at least a first interdigitated transducer including a plurality of interdigitated fingers disposed on a first surface of the substrate; and at least a first reflector including a plurality of gratings disposed on the first surface of the SAW device. At least one of: (1) a first plurality of the interdigitated fingers of the first interdigitated transducer has a first finger pitch and a first finger metal pitch ratio, and a second plurality of interdigitated fingers has a second finger pitch different from the first metal pitch and a second metal pitch ratio which is different from the first metal pitch ratio, and the first group of interdigitated fingers has a first surface mode resonance frequency, and the second group of interdigitated fingers has a second surface mode resonance frequency which is substantially the same as the first resonance frequency, and (2) a first plurality of the gratings of the first reflector has a first grating pitch and a first grating metal pitch ratio, and a second plurality of the gratings has a second grating metal pitch different from the first grating metal pitch and a second grating metal pitch ratio which is different from the first grating metal pitch ratio, and the first group of the gratings has a first grating surface mode resonance frequency, and the second group of the gratings has a second grating surface mode resonance frequency which is substantially the same as the first grating surface mode resonance frequency.

### BRIEF DESCRIPTION OF THE DRAWINGS

The example embodiments are best understood from the following detailed description when read with the accompanying drawing figures. It is emphasized that the various features are not necessarily drawn to scale, nor are the aspect ratios necessarily shown as they would exist in practice. In fact, the dimensions may be arbitrarily increased or decreased for clarity of discussion. Wherever applicable and practical, like reference numerals refer to like elements.

FIG. 1A and FIG. 1B each illustrate an exemplary acoustic resonator.

FIG. 2 shows a cross-sectional view of an acoustic resonator with a hybrid wafer substrate.

FIG. 3 illustrates an example of how the effective velocity of an acoustic wave in a SAW device may be a function of the metallization percentage of an interdigitated transducer.

FIG. 4 illustrates a portion of an acoustic resonator which includes an example embodiment of an interdigitated transducer.

FIG. 5 illustrates a portion of an acoustic resonator which includes an example embodiment of an acoustic reflector.

FIG. 6 illustrates a portion of an acoustic resonator which includes another example embodiment of an interdigitated transducer.

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the example embodiments. Such methods and apparati are clearly within the scope of the present teachings.

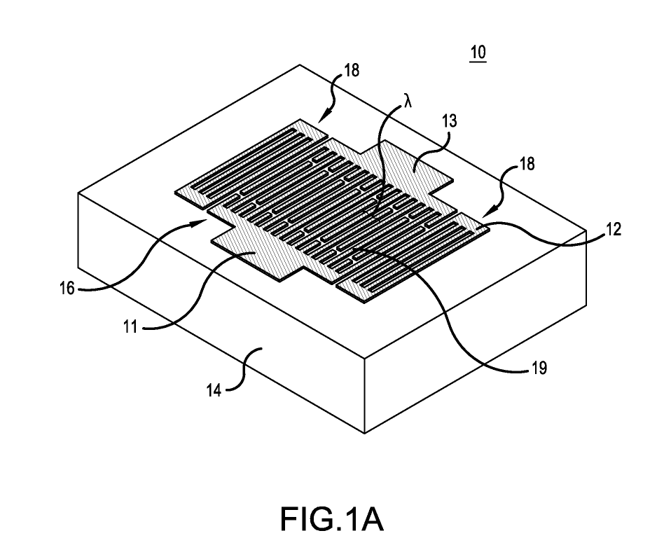

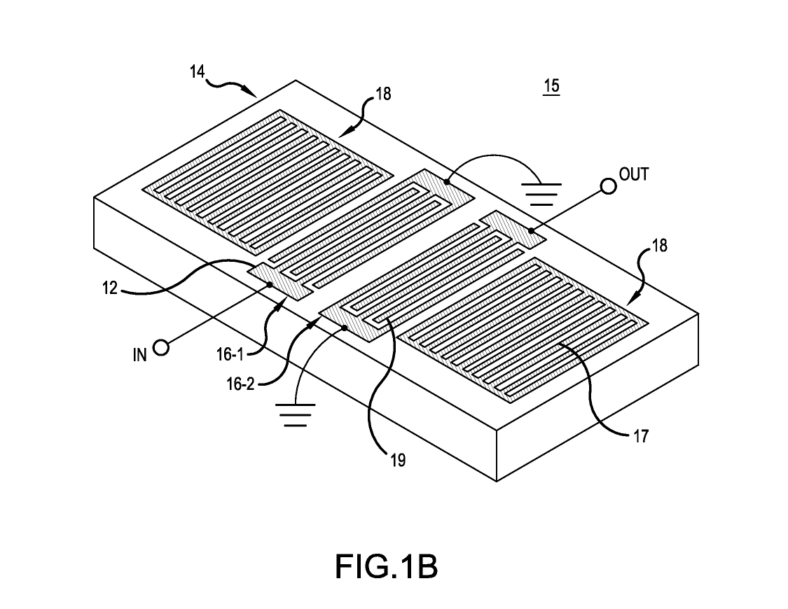

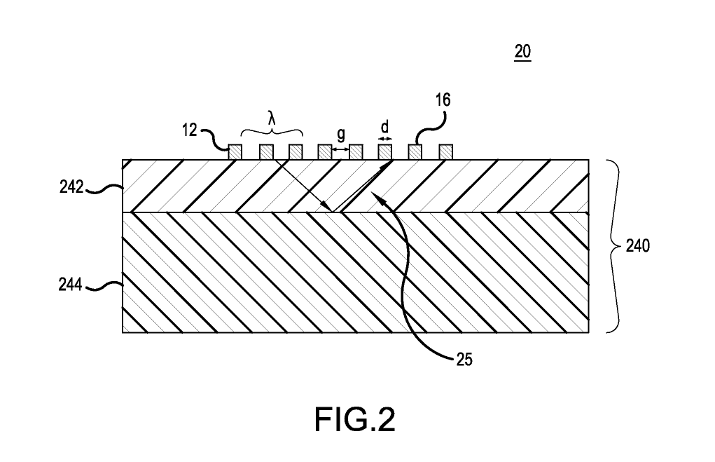

Without wishing to be bound by any theory, the present inventors have theorized, as illustrated in FIG. 2, that spurious resonance responses observed in SAW devices (e.g., resonators and filters) which employ a hybrid wafer substrate are related to and/or caused by bulk acoustic waves (BAW) 25, which are generated by an IDT (e.g., IDT 16) and launched into the substrate (e.g., substrate 240) reflecting at the bonding interface between the top piezoelectric material layer (e.g., 242) and the thicker base layer (e.g., 244), and then are re-absorbed by IDT 16. In general, spurious resonance responses could be generated by IDT 16, and/or by a reflector grating (not shown in FIG. 2, but see FIG. 1A) of SAW device 20.

The surface mode resonance frequency, F_{RES}, of a SAW resonator, can be found from:

F_{RES}=λ/νo, (1)

where λ (see FIGS. 1B and 2) is the finger pitch between adjacent like fingers connected to a same terminal of the IDT, and νo is the effective velocity of the surface acoustic wave between adjacent IDT fingers connected to opposite terminals of the IDT in the device.

The present inventors have recognized that the effective velocity νo of a surface acoustic wave in a SAW device depends upon, among other things, the metallization percentage of an IDT of the SAW device, and the relative electrode thickness h/λ. That is, νo is a function of (again, among other things) the finger metal pitch ratio. Here, the finger metal pitch ratio (FMP) is defined as:

FMP=[d/(d+g)], (2)

where d is the width of an interdigitated finger, and g is the gap between adjacent interdigitated fingers, as illustrated in FIG. 2.

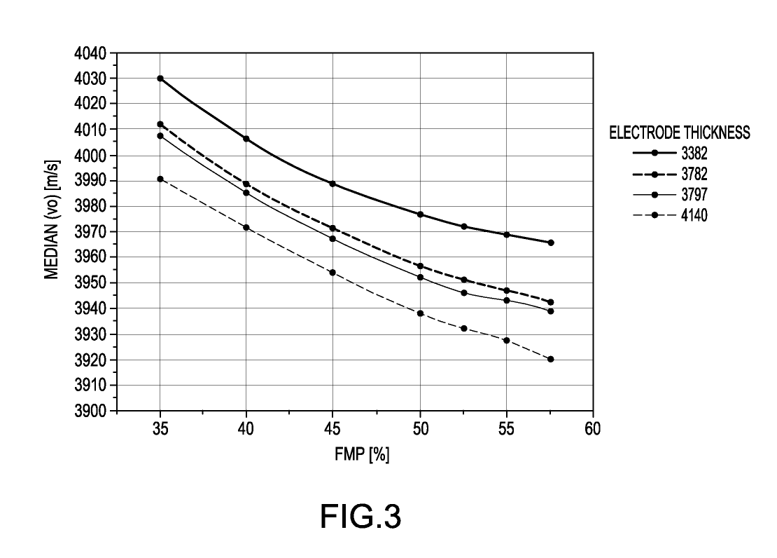

FIG. 3 illustrates an example of how the effective velocity νo of an acoustic wave in a SAW device may be a function of the metallization percentage of an interdigitated transducer. In the example shown in FIG. 3, as finger metal pitch ratio (FMP) increases, the effective velocity νo of the surface acoustic wave decreases.

The present inventors have further recognized that the velocity of a bulk acoustic wave (BAW velocity) in a hybrid wafer substrate depends on the piezoelectric top layer of the hybrid wafer substrate and the finger pitch λ between adjacent like fingers, but is not a function of the finger metal pitch ratio (FMP).

With this understanding, the present inventors have determined that the effects of spurious resonance responses from BAW propagation in a SAW device having a hybrid wafer substrate may be mitigated at least in part by varying of modulating the finger pitch λ and the finger metal pitch ratio (FMP) throughout different portions of the IDT in such a way that the surface mode resonance frequency, F_{RES}, of a SAW resonator remains constant or nearly constant throughout the IDT. Modulating the finger pitch λ de-tunes or lowers the Q-factor of the undesired BAW resonance modes (between the metal fingers at the surface and the bonded piezo-carrier wafer interface below). The reduced Q for the spurious BAW resonance modes in turn reduces the amplitude and impact of the spurious resonance modes in a case where these spurious resonance responses end up in the passband of another device in an overall system which includes the SAW device.

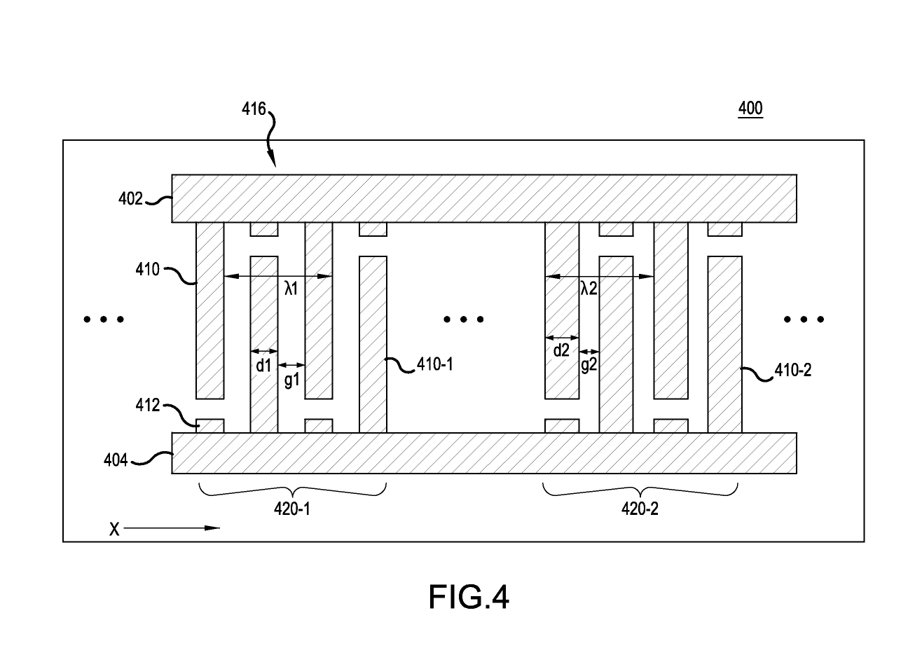

FIG. 4 illustrates a portion of an acoustic resonator 400 which includes an example embodiment of an interdigitated transducer (IDT) 416. In particular, an interdigitated transducer 416 is an example of an interdigitated transducer where the finger pitch λ and the finger metal pitch ratio (FMP) are varied or modulated across its length in the X direction. In some embodiments, interdigitated transducer (IDT) 416 may be employed in a SAW device such as SAW device 20 and may be disposed on the first surface of a hybrid wafer substrate, comprising at least a base layer comprising a first material, and a top layer comprising a second material different from the first material. In some embodiments, a SAW device may include two or more interdigitated transducers (IDTs) 416 disposed on a first surface of a substrate and separated and spaced apart from each other by a delay line.

Interdigitated transducer 416 includes a first terminal 402 and a second terminal 404 and a plurality of interdigitated fingers 410 each connected to one of the first and second terminals 402 and 404, and a plurality of “stubs” 412 each disposed opposite one of the interdigitated fingers 410.

Interdigitated transducer 416 includes a plurality of sections or regions extending in the X direction where the finger pitch λ varies from region to region. FIG. 4 illustrates a first region 420-1 corresponding to a first group of first interdigitated fingers 410-1 and a second region 420-2 corresponding to a second group of second interdigitated fingers 410-2. It should be understood that, in general, interdigitated transducer 416 may have more than two different regions where the interdigitated fingers 410 may all have different finger pitches λ than each other. That is, there may be a third group, a fourth group, etc. of interdigitated fingers which have different finger pitches λ than the finger pitches λ in some or all of the other groups. Of course, it is also possible that the finger pitches λ in some of the regions may be the same as each other, too.

In first region 420-1, first interdigitated fingers 410-1 are arranged at a first finger pitch λ1, and in second region 420-2, second interdigitated fingers 410-2 are arranged at a second finger pitch λ2. Accordingly, as explained above, a spurious BAW wave (e.g., BAW wave 25) generated at first region 420-1 will have a different spurious resonant frequency than a spurious BAW wave generated at second region 420-2. Therefore, the energy of any spurious resonant response from BAW propagation is spread among a plurality of frequencies, thereby reducing its amplitude and impact.

In some embodiments, interdigitated transducer 416 may have a large number (e.g., ten or more) of different regions where the interdigitated fingers 410 have different finger pitches λ in the different regions. In that case, the finger pitches λ of the pluralities of the interdigitated fingers 410 of the different regions 420 may be pseudorandomly distributed between a minimum finger pitch and a maximum finger pitch. Beneficially, this may spread the energy of any BAW spurious resonance responses rather evenly over a large number of frequencies, thereby reducing their amplitude and impact.

For proper operation of interdigitated transducer 416 and acoustic resonator 400, the surface mode resonance frequency, F_{RES} should be the same, or constant, or at least substantially the same, in all regions 420-1, 420-2, etc. As can be seen from equation (1) above, if the finger pitch λ is changed and it is desired to keep the surface mode resonance frequency, F_{RES}, constant, then the effective velocity of the surface acoustic wave, νo, should be adjusted or varied in a counteracting manner to the way that the finger pitch λ is changed. Beneficially, as seen above in FIG. 3, the effective velocity of the surface acoustic wave, νo, can be adjusted or varied in turn by adjusting or varying the finger metal pitch ratio (FMP).

Accordingly, as seen in FIG. 4, while the finger pitch λ is varied between first region 420-1 and second region 420-2, the width, d, of the interdigitated fingers, and the gap, g, between adjacent interdigitated fingers 410 are also varied between first region 420-1 and second region 420-2 so as to vary the finger metal pitch ratio (FMP) between first region 420-1 and second region 420-2. That is, in first region 420-1 first interdigitated fingers 410-1 have a first finger pitch λ1, a first width d1, and a first gap, g1, between adjacent first interdigitated fingers 410-1. In contrast, in second region 420-2 second interdigitated fingers 410-2 have a second finger pitch λ2, a second width d2, and a second gap, g2, between adjacent second interdigitated fingers 410-2. Beneficially, the values of first finger pitch λ1, first width d1, first gap, g1, second finger pitch λ2, second width d2, and second gap, g2 are selected such that the first surface mode resonance frequency, F_{RES1}, in first region 420-1 is the same, or substantially the same, as the second surface mode resonance frequency, F_{RES2}, in second region 420-2. Here, when we say that the first surface mode resonance frequency, F_{RES1}, in first region 420-1 is the same, or substantially the same, as the second surface mode resonance frequency, F_{RES2}, in second region 420-2, we mean that the surface mode resonance frequencies are maintained to be the same as each other within manufacturing tolerances of the device. If we define Δf=| (F_{RES1}−F_{RES2})|, then beneficially Δf<<0.01*F_{RES1}, and even more beneficially Δf<0.001*F_{RES1}. More generally, if we define the target surface mode resonant frequency for interdigitated transducer 416 to be F_{TARGET}, then the range of F_{RES} for all regions or sections of interdigitated transducer 416 should be substantially the same as each other (again, within manufacturing tolerance of the device)—beneficially within +/−1% of F_{TARGET}, and even more beneficially within +/−0.1% of F_{TARGET}.

As noted above, in general, interdigitated transducer 416 may have more than two different regions 420 where the interdigitated fingers 410 may all have different finger pitches λ than each other and different finger metal pitch ratios (FMPs) than each other. In general, finger pitches λ between pairs of interdigitated fingers 410 in interdigitated transducer 416 all may be different from each other, and finger metal pitch ratios (FMPs) of the pairs of interdigitated fingers 410 all may be different from each other, and each of the pairs of interdigitated fingers 410 may have a corresponding surface mode resonance frequency F_{RES} which are the same as, or substantially the same as, each other. Of course, it is also possible that the finger pitches λ and finger metal pitch ratios (FMPs) in some of the regions may be the same as each other, too. In some embodiments, the values of the widths d and the gaps g in the different regions may be selected so that the finger metal pitch ratios (FMPs) in the various regions are pseudorandomly distributed between a minimum value and a maximum value.

The present inventors have determined that the effects of spurious resonance responses from BAW propagation in a SAW device having a hybrid wafer substrate also may be mitigated at least in part by varying or modulating the grating pitch and the grating metal pitch ratio (GMP) throughout different portions or regions of the acoustic reflector(s) of the SAW device in place of, or in addition to, varying or modulating the finger pitch λ and the finger metal pitch ratio (FMP) throughout different portions of the IDT(s) of the SAW device.

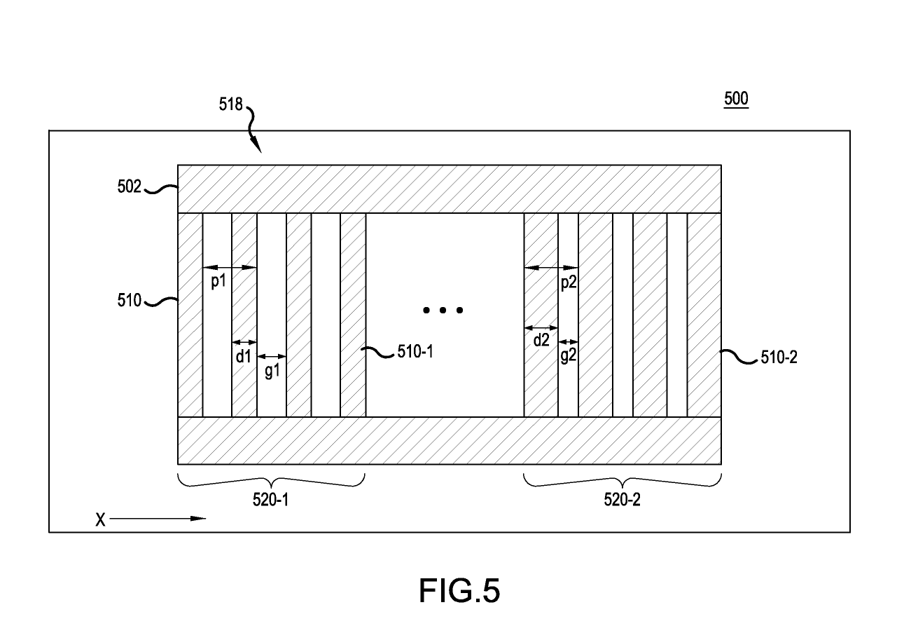

FIG. 5 illustrates a portion of an acoustic resonator 500 which includes an example embodiment of an acoustic reflector 518.

Acoustic reflector 518 includes a plurality of sections or regions extending in the X direction where the grating pitch p varies from region to region. FIG. 5 illustrates a first region 520-1 corresponding to first gratings 510-1 and a second region 520-2 corresponding to second gratings 510-2. That is, there may be a third group, a fourth group, etc. of gratings which have different grating pitches p than the grating pitches p in some or all of the other groups. It should be understood that in general reflector 518 may have more than two different regions where the gratings 510 may all have different grating pitches p than each other. Of course, it is also possible that the grating pitches p in some of the regions may be the same as each other, too.

In first region 520-1, first gratings 510-1 are arranged at a first grating pitch p1, and in second region 520-2, second gratings 510-2 are arranged at a second grating pitch p2. Accordingly, as explained above, a spurious BAW wave (e.g., BAW wave 25) generated at first region 520-1 will have a different spurious resonant frequency than a spurious BAW wave generated at second region 520-2. Therefore, the energy of any spurious resonant response from BAW propagation is spread among a plurality of frequencies, thereby reducing its amplitude and impact.

In some embodiments, reflector 518 may have a large number (ten or more) of different regions where the gratings 510 have different grating pitches p in the different regions. In that case, the grating pitches p of the pluralities of the gratings 510 of the different regions 520 may be pseudorandomly distributed between a minimum grating pitch and a maximum grating pitch. Beneficially, this may spread the energy of any BAW spurious resonance responses rather evenly over a large number of frequencies, thereby reducing their amplitude and impact.

In some embodiments, for proper operation of reflector 518 and acoustic resonator 500, the grating surface mode resonance frequency, F_{RES-GRATING} should be the same, or constant, or at least substantially the same, in all regions 520-1, 520-2, etc. If the grating pitch p is changed from one region 520 to another, and it is desired to keep the grating surface mode resonance frequency, F_{RES-GRATING}, constant in all regions 520, then the effective velocity of the surface acoustic wave, νo, should be adjusted or varied in a counteracting manner to the way that the grating pitch p is changed. Beneficially, the effective velocity of the surface acoustic wave, νo, can be adjusted or varied in turn by adjusting or varying the grating metal pitch ratio (GMP), where the grating metal pitch ratio (GMP) is defined as:

GMP=[d/(d+g)], (3)

where d is the width of a grating 510, and g is the gap between adjacent gratings 510.

Accordingly, as seen in FIG. 5, while the grating pitch p is varied between first region 520-1 and second region 520-2, the width, d, of the gratings, and the gap, g, between adjacent gratings 510 are also varied between first region 520-1 and second region 520-2 so as to vary the grating metal pitch ratio (GMP) between first region 520-1 and second region 520-2. That is, in first region 520-1 first interdigitated fingers 510-1 have a first grating pitch p1, a first width d1, and a first gap, g1, between adjacent first gratings 510-1. In contrast, in second region 520-2 second gratings 510-2 have a second grating pitch p2, a second width d2, and a second gap, g2, between adjacent second gratings 510-2. Beneficially, the values of first grating pitch p1, first width d1, first gap, g1, second grating pitch p2, second width d2, and second gap, g2 are selected such that the first grating surface mode resonance frequency, F_{RES-GRATING1} in first region 520-1 is the same, or substantially the same, as the second grating surface mode resonance frequency, F_{RES-GRATING2} in second region 520-2. Here, when we say that the first surface mode resonance frequency, F_{RES-GRATING1} in first region 520-1 is the same, or substantially the same, as the second grating surface mode resonance frequency, F_{RES-GRATING2} in second region 520-2, we mean that the grating surface mode resonance frequencies are maintained to be the same as each other within manufacturing tolerances of the device. If we define Δf=|(F_{RES-GRATING1}−F_{RES-GRATING2})|, then beneficially Δf<<0.01*F_{RES-GRATING1}, and even more beneficially Δf<0.001*F_{RES-GRATING1}. More generally, if we define the target grating surface mode resonant frequency for acoustic reflector to be F_{TARGET-GRATING}, then the range of F_{RES-GRATING} for all regions or sections of acoustic reflector 518 should be substantially the same as each other (again, within manufacturing tolerance of the device)—beneficially within +/−1% of F_{TARGET-GRATING}, and even more beneficially within +/−0.1% of F_{TARGET-GRATING}.

As noted above, in general, acoustic reflector 518 may have more than two different regions 520 where the gratings 510 may all have different grating pitches p than each other and different grating metal pitch ratios (GMPs) than each other. In general, grating pitches p between pairs of gratings 510 in acoustic reflector 518 all may be different from each other, and grating metal pitch ratios (GMPs) of the pairs of gratings 510 all may be different from each other, and each of the pairs of gratings 510 may have a corresponding grating surface mode resonance frequency F_{RES-GRATING} which are the same as, or substantially the same as, each other. Of course, it is also possible that the grating pitches p and grating metal pitch ratios (GMPs) in some of the regions may be the same as each other, too. In some embodiments, the values of the widths d and the gaps g in the different regions may be selected so that the finger metal pitch ratios (GMPs) in the various regions are pseudorandomly distributed between a minimum value and a maximum value.

In some embodiments, one or more reflectors 518 may be combined with one or more interdigitated transducers 416 in a common SAW device such as a SAW resonator or SAW filter. In that case, each of the reflectors may be configured with features described above with respect to reflector 518.

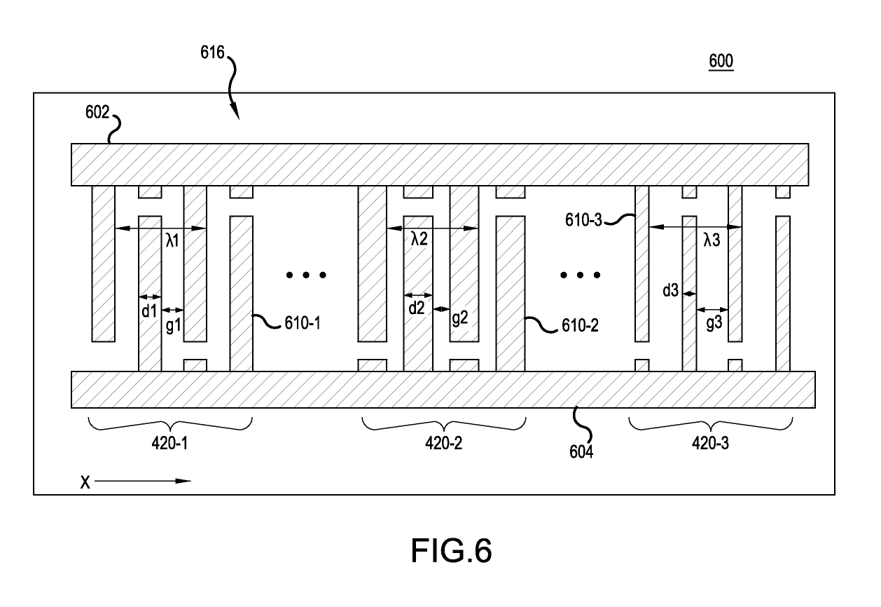

FIG. 6 illustrates a portion of an acoustic resonator 600 which includes another example embodiment of an interdigitated transducer 616. Interdigitated transducer 616 is similar in construction and operation to interdigitated transducer 416 described above, except that FIG. 6 explicitly shows three different regions 620-1, 620-2 and 620-3 having a first group of first interdigitated fingers 610-1, a second group of second interdigitated fingers 610-2, and a second group of third interdigitated fingers 610-3, respectively.

In first region 620-1 first interdigitated fingers 610-1 have a first finger pitch λ1, a first width d1, and a first gap, g1, between adjacent first interdigitated fingers 610-1. In second region 620-2 second interdigitated fingers 610-2 have a second finger pitch λ2, a second width d2, and a second gap, g2, between adjacent second interdigitated fingers 610-2. In third region 620-3 third interdigitated fingers 610-3 have a third finger pitch λ3, a third width d3, and a third gap, g3, between adjacent third interdigitated fingers 610-3. Beneficially, the values of first finger pitch λ1, first width d1, first gap, g1, second finger pitch λ2, second width d2, second gap, g2, third finger pitch λ3, third width d3, and third gap, g3 are selected such that the surface mode resonance frequency, F_{RES1}, in first region 620-1 is the same, or approximately the same, as the surface mode resonance frequency, F_{REs2}, in second region 620-2 and the surface mode resonance frequency, F_{RES3}, in third region 620-3. That is, a first finger metal pitch ratio (FMP1) in first region 620-1, a second finger metal pitch ratio (FMP2) in second region 620-2, and a third finger metal pitch ratio (FMP3) in third region 620-3 may be selected in view of λ1, λ2 and λ3 such that the surface mode resonance frequency, F_{RES1}, in first region 620-1 is the same, or approximately the same, as the surface mode resonance frequency, F_{RES2}, in second region 620-2 and the surface mode resonance frequency, F_{RES3}, in third region 620-3.

As described above, by varying or modulating the finger pitch and finger metal pitch ratio (FMP) in one or more interdigitated transducers and/or reflectors of a SAW device produced on a hybrid wafer substrate, the surface wave propagation characteristics of the SAW device may be essentially maintained unchanged, while the spurious bulk wave propagation characteristics are distributed over a plurality (e.g., a large number) of frequencies so as to reduce their amplitude and effect.

While example embodiments are disclosed herein, one of ordinary skill in the art appreciates that many variations that are in accordance with the present teachings are possible and remain within the scope of the appended claims. The embodiments therefore are not to be restricted except within the scope of the appended claims.

1. A surface acoustic wave (SAW) device, comprising:
a substrate; and
at least a first interdigitated transducer disposed on a first surface of the substrate,
wherein the first interdigitated transducer includes a plurality of interdigitated fingers, including at least a first group of first interdigitated fingers having a first finger pitch and a second group of second interdigitated fingers having a second finger pitch which is different from the first finger pitch, and
wherein the first group of first interdigitated fingers has a first finger metal pitch ratio, and the second group of second interdigitated fingers has a second finger metal pitch ratio which is different from the first finger metal pitch ratio, and
wherein the first group of first interdigitated fingers has a first surface mode resonance frequency, and the second group of second interdigitated fingers has a second surface mode resonance frequency which is substantially the same as the first surface mode resonance frequency.

2. The SAW device of claim 1, wherein the first interdigitated transducer further includes a third group of third interdigitated fingers having a third finger pitch which is different from the first finger pitch and the second finger pitch, and having a third finger metal pitch ratio which is different from the first finger metal pitch ratio and the second finger metal pitch ratio, and wherein the third group of third interdigitated fingers has a third surface mode resonance frequency which is substantially the same as the first surface mode resonance frequency.

3. The SAW device of claim 1, wherein finger pitches between pairs of interdigitated fingers in the first interdigitated transducer are all different from each other and wherein finger metal pitch ratios of the pairs of interdigitated fingers are all different from each other, and wherein each of the pairs of interdigitated fingers has a corresponding surface mode resonance frequency which is substantially the same as the first surface mode resonance frequency.

4. The SAW device of claim 3, wherein the finger pitches of the groups of interdigitated fingers are pseudorandomly distributed between a minimum finger pitch and a maximum finger pitch.

5. The SAW device of claim 1, wherein the finger metal pitch ratios of the groups of interdigitated fingers are pseudorandomly distributed between a minimum finger metal pitch ratio and a maximum finger metal pitch ratio.

6. The SAW device of claim 1, further comprising at least one reflector disposed on the first surface of the substrate, wherein the at least one reflector comprises a plurality of gratings, including a first group of first gratings have a first grating pitch and a first grating metal pitch ratio, and a second group of second gratings have a second grating pitch and a second grating metal pitch ratio, and
wherein the first group of first gratings has a first grating resonance frequency, and the second group of second gratings has a second grating resonance frequency which is substantially the same as the first grating resonance frequency.

7. The SAW device of claim 1, further comprising a second interdigitated transducer disposed on a first surface of the substrate, separated and spaced apart from the first interdigitated transducer by a delay line, wherein the second interdigitated transducer includes a second plurality of interdigitated fingers, including at least a third group of third interdigitated fingers having a third finger pitch and a fourth group of fourth interdigitated fingers having a fourth finger pitch which is different from the third finger pitch, and
wherein the third group of third interdigitated fingers has a third finger metal pitch ratio, and the fourth group of fourth interdigitated fingers has a fourth finger metal pitch ratio which is different from the third finger metal pitch ratio, and
wherein the third group of third interdigitated fingers has a third resonance frequency, and the fourth group of fourth interdigitated fingers has a fourth resonance frequency which is substantially the same as the third resonance frequency.

8. The SAW device of claim 7, wherein the first resonance frequency is substantially the same as the third resonance frequency.

9. The SAW device of claim 7, further comprising at least one reflector disposed on the first surface of the SAW device, wherein the at least one reflector comprises a plurality of gratings, including a first group of first gratings having a first grating pitch and a first grating metal pitch ratio, and a second group of second gratings having a second grating pitch and a second grating metal pitch ratio, and
wherein the first group of first gratings have a first grating resonance frequency, and the second group of second gratings have a second grating resonance frequency which is substantially the same as the first grating resonance frequency.

10. The SAW device of claim 1, wherein the substrate comprises a hybrid wafer substrate comprising at least a base layer comprising a first material, and a top layer comprising a second material different from the first material.

11. The SAW device of claim 10, wherein the base layer comprises one selected from the group consisting of silicon, sapphire and glass, and wherein the top layer comprises one selected from the group consisting of LiTaO3 and LiNbO3.

12. A surface acoustic wave (SAW) device, comprising:
a substrate;
at least a first interdigitated transducer including a plurality of interdigitated fingers disposed on a first surface of the substrate; and
at least a first reflector including a plurality of gratings disposed on the first surface of the substrate,
wherein at least one of:
(1) a first group of the interdigitated fingers of the first interdigitated transducer has a first finger pitch and a first finger metal pitch ratio, and a second group of interdigitated fingers has a second finger pitch different from the first metal pitch and a second metal pitch ratio which is different from the first metal pitch ratio; and the first group of interdigitated fingers has a first surface mode resonance frequency, and the second group of interdigitated fingers has a second surface mode resonance frequency which is substantially the same as the first resonance frequency, and
(2) a first group of the gratings of the first reflector has a first grating pitch and a first grating metal pitch ratio, and a second group of the gratings has a second grating metal pitch different from the first grating metal pitch and a second grating metal pitch ratio which is different from the first grating metal pitch ratio, wherein the first group of the gratings has a first grating surface mode resonance frequency, and the second group of the gratings has a second grating surface mode resonance frequency which is substantially the same as the first grating surface mode resonance frequency.

13. The SAW device of claim 12, wherein at least one of:
(1) a third group of the interdigitated fingers has a third finger pitch different from the first metal pitch and a first finger metal pitch ratio which is different from the first metal pitch ratio; and
(2) a third group of the gratings of the first reflector has a third grating pitch different from the first grating metal pitch and a third grating metal pitch ratio which is different from the first grating metal pitch ratio.

14. The SAW device of claim 12, wherein at least one of:
(1) surface mode resonance frequencies of the interdigitated fingers of the first interdigitated transducer are all substantially the same as each other, and
(2) grating surface mode resonance frequencies of the gratings of the first reflector are all substantially the same as each other.

15. The SAW device of claim 12, wherein finger pitches between pairs of interdigitated fingers in the first interdigitated transducer are all different from each other and wherein finger metal pitch ratios of the pairs of interdigitated fingers are all different from each other.

16. The SAW device of claim 15, wherein the finger pitches between the pairs of interdigitated fingers are pseudorandomly distributed between a minimum finger pitch and a maximum finger pitch.

17. The SAW device of claim 16, wherein the finger metal pitch ratios of the pairs of interdigitated fingers are pseudorandomly distributed between a minimum finger metal pitch ratio and a maximum finger metal pitch ratio.

18. The SAW device of claim 17, wherein the substrate comprises a hybrid wafer substrate comprising at least a base layer comprising a first material and a top layer comprising a second material different from the first material.
